(19) United States
(12) Patent Application Publication
(10) Pub. No.: US 2025/0156700 A1
(43) Pub. Date: May 15, 2025

(54) CIRCULAR POLARIZATION-RESOLVED PHOTONIC ARTIFICIAL SYNAPSE DEVICE AND PREPARATION METHOD THEREFOR

(71) Applicant: The Hong Kong Polytechnic University Shenzhen Reseach Institute, Shenzhen (CN)

(72) Inventors: Mingjie LI, Shenzhen (CN); Qi Liu, Shenzhen (CN)

(73) Assignee: The Hong Kong Polytechnic University Shenzhen Reseach Institute, Shenzhen (CN)

(21) Appl. No.: 18/509,597

(22) Filed: Nov. 15, 2023

(51) Int. Cl. G06N 3/067; H10K 71/12; H10K 71/40; H10K 71/60; H10K 85/20; H10K 85/50

(52) U.S. Cl. CPC G06N 3/0675; H10K 71/12; H10K 71/40; H10K 71/60; H10K 85/221; H10K 85/50

(57) ABSTRACT

The embodiments relate to the technical field of optoelectronic devices and to a circular polarization-resolved photonic artificial synapse (CPL-resolved PAS) device and a preparation method therefor. The CPL-resolved PAS device includes a heterostructure based on a helical chiral perovskite (H-PVK) and a single-wall carbon nanotube (SWNT). The heterostructure includes a H-PVK layer and a SWNT layer. The H-PVK layer and the SWNT layer contact and overlap, and a heterojunction is formed between the H-PVK layer and the SWNT layer. Using the chiral optoelectronic response characteristics of the H-PVK and the carrier conduction characteristics of the SWNT, the heterostructure is able to achieve nano-ampere-level distinguishable photocurrent response for circular-polarization UV light with different chirality. The CPL-resolved PAS device obtained by the present disclosure has good stability and can be prepared on a large scale.

### TECHNICAL FIELD

The present disclosure relates to the technical field of optoelectronic devices, in particular to a circular polarization-resolved photonic artificial synapse device and a preparation method therefor.

### BACKGROUND

More than 80% of the information input into the human brain is obtained through vision, which makes the vision system one of the most important perceptual systems. A typical vision system consists of a retina that receives light signals and visual cortex that implements parallel cognition. In the vision system, the retina simplifies the image by time coding method, preliminarily processes the visual information, and then transmits the signal to the visual cortex. This neuromorphic feature helps to achieve high efficiency and low power consumption. Inspired by the human vision system, photonic artificial synapse (PAS) devices with neuromorphic features arouse great research interest and are widely studied in the field of machine vision. However, most of the reported PAS devices are only sensitive to color (wavelength) and light intensity and cannot detect circularly polarized light (CPL). The circular polarization-resolved photonic artificial synapse (CPL-resolved PAS) device plays an important role in constructing circular polarization-dependent neuromorphic vision systems and realizing visual sensing, encrypted communication, virtual reality, biological imaging, object recognition, optical communication, and so on. However relevant studies are currently lacking.

Therefore, the prior art still needs to be improved and developed.

### SUMMARY

In view of the deficiencies above, the purpose of the present disclosure is to provide a circular polarization-resolved photonic artificial synapse (CPL-resolved PAS) device and a preparation method therefor, aiming to solve the problem that the reported PAS devices cannot detect CPL.

Chiral perovskites, chiral organic molecules, conjugated polymers, and other materials with circular dichroism (CD) response lay the foundation for direct detection of CPL and identification of CPL handedness (including left-handed CPL (LCP) and right-handed CPL (RCP)). In these chiral materials, the chiral molecules such as α-Methylbenzylamine enantiomers (α-MBA), β-Methylphenethylammonium (β-MPA), 1-Cyclohexylethylammonium (CHEA), etc. are introduced into the helical chiral perovskite (H-PVK). Owing to the low-cost solution processing method, the tunable band gap, and the excellent chiroptic performance of the chiral perovskite, the chiral perovskite arouses extensive research. With the interaction between chiral ligands and the BX₆⁴⁻ matrix (B═Pb, Sn, Ge; X═I, Br, Cl), the chiral perovskites exhibit high circular dichroism (CD). However, the conductivity of the chiral perovskite is low, impeding the optoelectric performance of devices constructed with the chiral perovskites.

Combining chiral perovskite (PVK) with high-mobility semiconductors can promote the transfer of photoinduced carriers and circumvent poor carrier transport. Therefore, exploration of H-PVK-based heterostructure is essential in developing high-performance CPL-resolved ultraviolet (UV) PAS devices.

Therefore, in view of the deficiencies above, the purpose of the present disclosure is: 1) to provide a heterostructure based on a H-PVK and a single-wall carbon nanotube (SWNT) with efficient charge carrier transport and excellent photo-response performance; and 2) take the heterostructure as a functional layer, providing a CPL-resolved PAS device with bionic function as artificial synapse.

Specifically, the disclosed technical scheme of the present disclosure is as follows:

In a first aspect, the present disclosure can be viewed as providing a heterostructure based on a helical chiral perovskite (H-PVK) and a single-wall carbon nanotube (SWNT). The heterostructure includes a H-PVK layer and a SWNT layer. The H-PVK layer and the SWNT layer contact and overlap, and a heterojunction is formed between the H-PVK layer and the SWNT layer.

The present disclosure can be viewed as providing a heterostructure based on the H-PVK and the SWNT. Using the chiral optoelectronic response characteristics of the H-PVK and the high carrier transport characteristics of the SWNT, the heterostructure can achieve nano-ampere-level distinguishable photocurrent response for circularly polarized UV light with different chirality.

Optionally, the H-PVK includes one or more of (S-α-MBA)PbI₃, (R-α-MBA)PbI₃, (S-NEA)PbI₃, (R-NEA)PbI₃, (S-MPA)PbI₃, (R-MPA)PbI₃, (S-α-MBA)PbBr₃, and (R-α-MBA)PbBr₃.

Optionally, a thickness of the H-PVK layer is 40-90 nm.

Optionally, a thickness of the SWNT layer is 2-10 nm.

In a second aspect, the present disclosure can also be viewed as providing a method for preparing the heterostructure based on the H-PVK and the SWNT. The method can be broadly summarized by the following steps:
Providing a substrate;
Depositing a SWNT layer on the substrate;
Depositing a H-PVK layer on the SWNT layer.

Optionally, the step of depositing the SWNT layer on the substrate is by a solution method. The details are shown below and are not repeated here.

Optionally, the step of depositing the H-PVK layer on the SWNT layer is by a solution method. The details are shown below and are not repeated here.

In a third aspect, the present disclosure can also be viewed as providing a CPL-resolved PAS device. The CPL-resolved PAS device comprises a heterostructure based on a H-PVK and a SWNT. The heterostructure includes a H-PVK layer and a SWNT layer. The H-PVK layer and the SWNT layer contact and overlap, and a heterojunction is formed between the H-PVK layer and the SWNT layer.

The present disclosure can also be viewed as providing the CPL-resolved PAS device comprising the heterostructure. Using the chiral optoelectronic response characteristics of the H-PVK and the high carrier transport characteristics of the SWNT, the heterostructure is able to achieve nano-ampere-level distinguishable photocurrent response for circular-polarization UV light with different chirality. In addition, the CPL-resolved PAS device obtained by the present disclosure has good stability and can be prepared at a large scale.

Optionally, the CPL-resolved PAS device includes a substrate, a SWNT layer arranged on the substrate, electrodes arranged on two ends of the SWNT layer, and a H-PVK layer arranged on an area uncovered by the electrodes of the SWNT layer. A heterojunction is formed between the H-PVK layer and the SWNT layer.

Optionally, the substrate is a silicon wafer, a sapphire, or a quartz, with a SiO₂ layer on a surface of the substrate. The SiO₂ layer is attached to the SWNT layer.

Optionally, the electrodes arranged on the two ends include a first electrode and a second electrode. A material of the first electrode includes one of Au, Pt, Ag, ITO, Al, and Ni. A material of the second electrode includes one of Cr, Ti, Ag, ITO, Al, and Ni.

Optionally, the H-PVK includes one or more of (S-α-MBA)PbI₃, (R-α-MBA)PbI₃, (S-NEA)PbI₃, (R-NEA)PbI₃, (S-MPA)PbI₃, (R-MPA)PbI₃, (S-α-MBA)PbBr₃, and (R-α-MBA)PbBr₃.

Optionally, a thickness of the H-PVK layer is 40-90 nm.

Optionally, a thickness of the SWNT layer is 2-10 nm.

In a fourth aspect, the present disclosure can also be viewed as providing a method for preparing a CPL-resolved PAS device. The method can be broadly summarized by the following steps:
Providing a substrate;
Depositing a SWNT layer on the substrate;
Depositing electrodes on two ends of the SWNT layer;
Depositing a H-PVK layer on an area uncovered by the electrodes of the SWNT layer.

Optionally, the step of depositing the SWNT layer on the substrate is by a solution method.

Further optionally, the step of depositing the SWNT layer on the substrate is by a solution method, comprising:
Providing a SWNT disperser;
Immersing the substrate in the SWNT disperser for 12-48 hours, and then taking the immersed substrate out, and heating the immersed substrate at 90-150° C. for 15-180 minutes, and depositing the heated substrate to obtain the SWNT layer on the substrate.

Optionally, the SWNT disperser is prepared by dispersing the SWNT in solvents such as toluene, N, N-dimethylformamide (DMF), N-methylpyrrolidone (NMP) and the like.

Optionally, the step of preparing the high-carrier transport characteristic SWNT is as follows: firstly, mixing poly [9-(1-octylnonyl)-9H-carbazole](PCz) and carbon-nanotube powder into toluene, ultrasonically treating, then centrifuging to remove insoluble substances, and taking supernatant out to obtain the SWNT with semiconductor properties. The collected supernatant containing the SWNT is diluted with chloroform for later use.

The solvent in the supernatant mentioned above is toluene. Chloroform is miscible with toluene and is volatile, which is beneficial to the deposition of the SWNT on the substrate.

In one embodiment, the step of preparing the high-carrier transport characteristic SWNT is as follows: firstly, mixing 5 mg of poly [9-(1-octylnonyl)-9H-carbazole](PCz) and 5 mg of carbon-nanotube powder into 20 ml of toluene, ultrasonically treating for 1 h, then centrifuging at 10000-18000 g (e.g. 15000 g) for 1 h to remove insoluble substances, and taking supernatant out to obtain the SWNT with semiconductor properties. The collected supernatant containing SWNT is diluted with chloroform for later use.

Optionally, the step of depositing the H-PVK layer on the area uncovered by the electrodes of the SWNT layer is by a solution method.

Further optionally, the step of depositing the H-PVK layer on the area uncovered by the electrodes of the SWNT layer is by the solution method, comprising:
Providing a H-PVK solution;
Spin-coating the H-PVK solution on the area uncovered by the electrodes of the SWNT layer a spin speed of 3500-5000 rpm for 30-50 seconds in an inert atmosphere, then annealing the spin-coated H-PVK at 80-100° C. for 10-60 minutes, and depositing the annealed H-PVK on the area uncovered by the electrodes of the SWNT layer to obtain the H-PVK layer.

Among them, the H-PVK solution is prepared by dispersing H-PVK in toluene, N, N-dimethylformamide (DMF), N-methylpyrrolidone (NMP), dimethyl sulfoxide (DMSO) and other solvents.

Among them, a concentration of the H-PVK solution is 0.25-1 mol·L⁻¹.

Taking MBAPbI₃ with CPL-UV response as an example, the preparation steps of the chiral perovskite are introduced.

The chiral perovskite (MBAPbI₃) with CPL-UV response is prepared by the following steps: firstly, dissolving a chiral amine (R-MBA or S-MBA) in methanol; adding HI dropwisely and stirring; removing the solvent by rotary evaporation to obtain the (R-α-MBA or S-α-MBA)PbI white powder; finally, collecting and washing the powder, drying the powder in vacuum overnight; dissolving the (R-/S-α-MBA)I templated by different α-methylbenzylamine enantiomers and PbI₂ with an equal molar ratio into DMF to obtain the chiral perovskite of Chiral 1D (R-MBAPbI₃) (abbreviated as 1D-R) and Chiral 1D (S-MBAPbI₃) (abbreviated as 1D-S).

In a specific embodiment, the chiral perovskite (MBAPbI₃) with UV CPL response is prepared by the following steps: firstly, dissolving 5.3 mL (0.0416 mol) of chiral amine (R-MBA or S-MBA) in 20 ml of methanol; adding 5 ml (0.0416 mol) of HI drop wisely within 15 minutes and stirring at 0° C. for 2 hours; removing the solvent by rotary evaporation to obtain the (R-α-MBA or S-α-MBA)PbI white powder; finally, collecting and washing the powder, drying the powder in vacuum overnight; dissolving the (R-/S-α-MBA)I templated by different α-methyl benzylamine enantiomers and PbI₂ with an equal molar ratio into DMF to obtain the chiral perovskite solution of 1D-R and 1D-S with the concentration of 0.3 mol L⁻¹.

Optionally, before the step of depositing the SWNT layer on the substrate, it further comprises the step of pretreating the substrate, which specifically comprises the following steps: ultrasonically cleaning the substrate with acetone, ethanol, and distilled water for 10-15 minutes in sequence, and then treating the substrate with UV-ozone for 10-15 minutes.

Optionally, photo etching and electron-beam evaporation can be used in the step of depositing the electrodes on the two ends of the SWNT layer.

Beneficial effects of the present disclosure are as follows:
1) The present disclosure adopts the solution method to prepare the H-PVK layer and the SWNT layer respectively, which has the characteristics of low cost, high stability, UV CPL response and the like, and is easy to realize large-scale preparation, and has great potential to construct circular polarization-enhanced ultraviolet neuromorphic vision systems.
2) According to the present disclosure, with efficient charge carrier transport performance provided by the SWNT, H-PVK the CPL-resolved UV PAS device, constructed by H-PVK (1D-R, 1D-S), can reach nano-ampere-level photocurrent response for LCP and RCP UV light at the wavelength of 395 nm, and resolves response preferences.
3) The CPL-resolved UV PAS device of the present disclosure provides CPL-modulated methods, light intensity, and wavelength to realize the simulation for biological synapse activity, which increases the modulating flexibility of the PAS device.

### BRIEF DESCRIPTION OF THE DRAWINGS

FIG. 1 is a schematic flowchart of a method for preparing a SWNT.

FIG. 2 is a schematic flowchart of a method for preparing a CPL-resolved PAS device.

FIG. 3 is a schematic diagram of a structure of a CPL-resolved PAS device.

FIG. 4 is a schematic diagram of an X-ray diffraction spectra of an (S-α-MBA)PbI₃.

FIG. 5 is a schematic diagram of a UV-visible absorption spectra of an (S-α-MBA)PbI₃.

FIG. 6 is a schematic diagram of a CD spectra of an (S-α-MBA)PbI₃.

FIG. 7 is a schematic diagram of a Raman spectra of a SWNT.

FIG. 8 is a schematic diagram of a response of a 1D-S based PAS device excited by consecutive LCP/RCP UV light spikes (395 nm, 10 uW cm⁻²).

FIG. 9 is a schematic diagram of an X-ray diffraction spectra of a (R-α-MBA)PbI₃.

FIG. 10 is a schematic diagram of a UV-visible absorption spectra of a (R-α-MBA)PbI₃.

FIG. 11 is a schematic diagram of a CD spectra of a (R-α-MBA)PbI₃.

FIG. 12 is a schematic diagram of a response of a 1D-R based PAS device excited by consecutive UV LCP/RCP light spikes (395 nm, 10 uWcm⁻²).

FIG. 13 is a schematic diagram of a response of a 1D-S based PAS device excited by consecutive UV LCP light spikes (395 nm) at different intensities.

### DETAILED DESCRIPTION OF THE EMBODIMENTS

The present disclosure can be viewed as providing a circular polarization-resolved photonic artificial synapse (CPL-resolved PAS) device and a preparation method therefor. In order to make the purposes, technical schemes, and effects of the present disclosure clearer and more explicit, the present disclosure is further explained in detail below. It should be understood that the specific embodiments described herein are used only to explain the present disclosure and are not used to limit the present disclosure.

### Embodiment 1

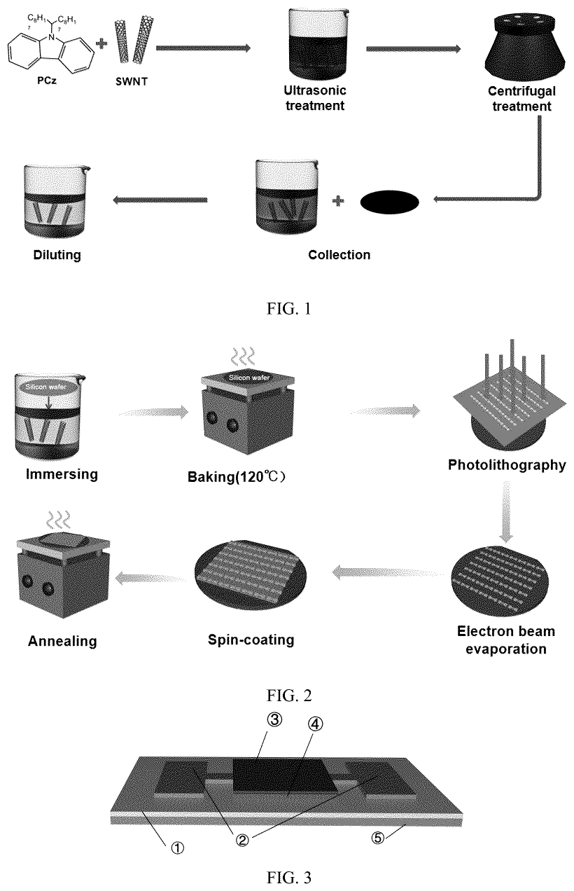

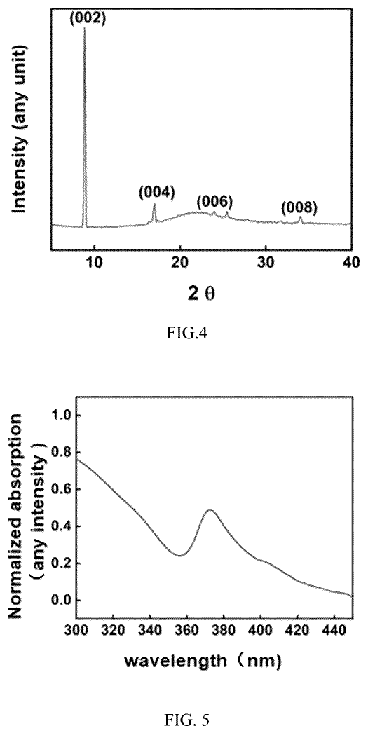

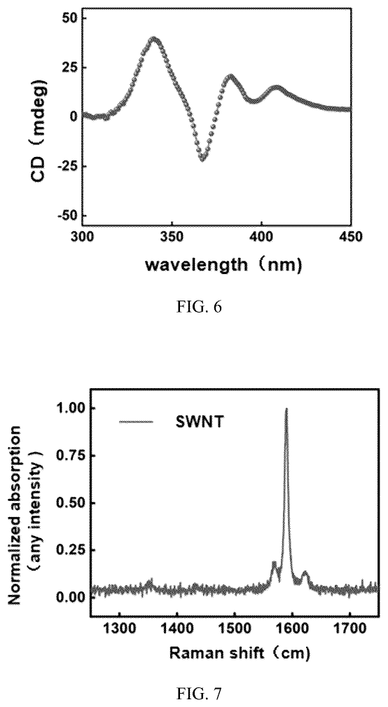

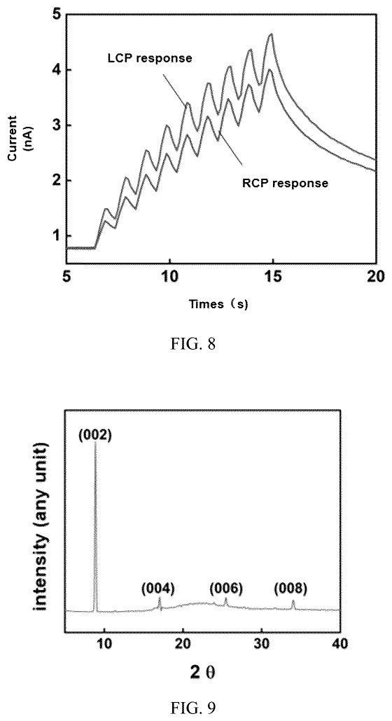

As shown in FIGS. 1-3, a CPL-resolved PAS device in the present embodiment 1 of the present disclosure comprises a silicon wafer with a SiO₂ layer on a surface of the silicon wafer, a single-wall carbon nanotube (SWNT) layer arranged on the silicon wafer with the SiO₂ layer on the surface of the silicon wafer, two electrodes arranged on two ends of the SWNT layer, a helical chiral perovskite (H-PVK) layer arranged on an area uncovered by the two electrodes on the SWNT layer. A heterojunction is formed between the H-PVK layer and the SWNT layer. Therein: \textcircled{1} SiO₂ layer; \textcircled{2} electrode; \textcircled{3} H-PVK layer; \textcircled{4} SWNT layer; \textcircled{5} silicon wafer. The preparation method for the CPL-resolved PAS device in the present embodiment of the present disclosure was as follows:
S1-1: A chiral iodized salt (S-α-MBA)I was prepared: Around-bottomed flask of 25 mL was ultrasonically cleaned with acetone, isopropanol, ethanol and deionized water in sequence, dried by nitrogen, dried at 80° C. for 1 hour, and then cooled for later use. A quantity of S-type chiral amine (S-MBA) (5.3 mL) and a quantity of methanol (20 mL) from a fume hood were put into the round-bottomed flask, First stirring was performed for dissolving fully, and the mixture solution was transferred to an ice bath environment at 0° C. A quantity of hydriodic acid (5 mL) was added dropwise in 15 minutes to obtain a mixture, and the mixture was stirred for 2 hours. The ice bath was removed, and a solvent was evaporated under a condition of oil bath at 80° C. to obtain (S-α-MBA)I white powder. The powder was collected and then washed twice with ether, and then dried in a vacuum overnight.
S1-2: A chiral perovskite (S-α-MBA)PbI₃ was prepared: a glass bottle of 2 mL was ultrasonically cleaned with acetone, isopropanol, ethanol and deionized water in sequence, dried by nitrogen, dried at 80° C. for 1 hour and then cooled for later use. 460 mg of PbI₂, 248 mg of (S-α-MBA)I, and 1 mL of DMF from a glove box were mixed in the glass bottle of 2 mL to obtain a mixture, and the mixture was completely dissolved by stirring the mixture at 60° C. for 2 hours to obtain an (S-α-MBA)PbI₃ solution (1 mol/L). The (S-α-MBA)PbI₃ solution (1 mol/L) of 300 μL and the DMF of 700 μL were mixed to obtain an (S-α-MBA)PbI₃ solution (0.3 mol/L) for later use. The X-ray diffraction (XRD) spectrum, ultraviolet-visible (UV-visible) absorption spectrum and circular dichroism (CD) absorption spectrum of (S-α-MBA)PbI₃ are shown in FIG. 4, FIG. 5, and FIG. 6 respectively.
S1-3: A SWNT was prepared: A glass bottle of 50 mL was ultrasonically cleaned with acetone, isopropanol, ethanol and deionized water in sequence, dried by nitrogen, dried at 80° C. for 1 hour and then cooled for later use. 5 mg of poly [9-(1-octylnonyl)-9H-carbazole](PCz), 5 mg of carbon-nanotube powder first and 20 mL of toluene second were mixed in the glass bottle, and an ultrasonic treatment was performed for 1 hour to obtain a carbon-nanotube precursor solution. The precursor solution was centrifuged at a parameter of 15000 g for 1 hour to remove insoluble substances, and a supernatant of the precursor solution was taken out and diluted with chloroform of the same volume to obtain the SWNT. The Raman spectrum of the SWNT was shown in FIG. 7, and the corresponding Raman shift (1600) peak proved that high-quality SWNT with semiconductor properties were obtained.
S1-4: A 1D-S based UV PAS device was prepared: A SiO₂ substrate with a thickness of 300 nm was ultrasonically cleaned with acetone, isopropanol, ethanol and deionized water in sequence, and then was immersed in a dispersion solution of the SWNT for 24 hours, and then the SiO₂ substrate was taken out and then baked at 120° C. for 15 minutes to deposit an SWNT layer. Au/Ti electrodes were prepared by photoetching and electron beam evaporation. The thickness of Au and Ti were 45 nm and 5 nm, respectively, and the width of a channel of the electrodes was 10 microns. The SiO₂ substrate with the SWNT and the electrodes was processed by ultraviolet ozone, and then an S-type chiral perovskite solution (50 μL, 0.3 mol/L) was spin-coated in a nitrogen atmosphere at a speed of 4000 rpm for 30 seconds by a spin coater to obtain a chiral perovskite layer. The thickness of the chiral perovskite layer was about 70 nm, and then the chiral perovskite layer was placed on a hot plate and annealed at 95° C. for 15 minutes. Finally, the 1D-S based UV PAS device was obtained.
S1-5: Bionic function test of the 1D-S based UV PAS device was performed. Monochromatic light source, linear polarizer, quarter-wave plate, probe station, and semiconductor analyzer were used for the test of polarization-dependent synaptic behavior. The monochromatic light was generated by the LED purchased from Thorlabs, the frequency of the polarized light signal was controlled by a signal generator, and the 1D-S based UV PAS device was connected to the Keithley 4200 through two Au probes of the probe station. The response of the 1D-S based UV PAS device excited by consecutive LCP/RCP light spikes (395 nm, 10 uWcm⁻²) is shown in FIG. 8.

### Embodiment 2

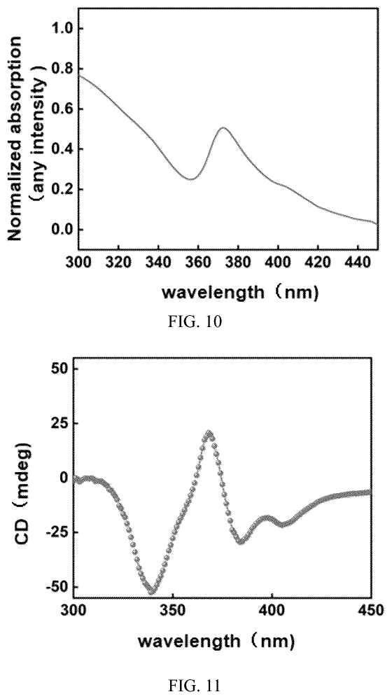

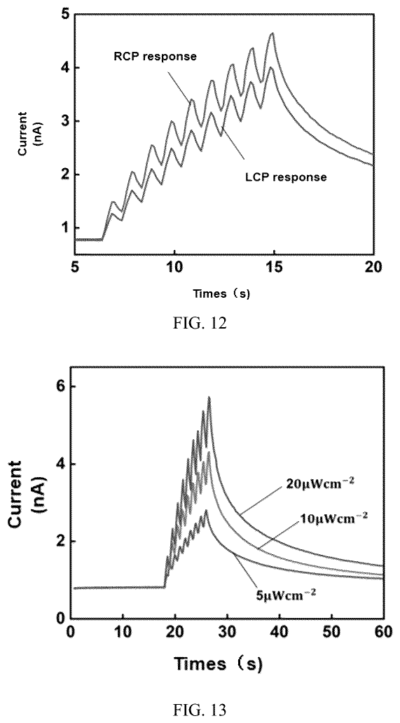

The preparation method of the CPL-resolved PAS device in embodiment 2 of the present disclosure was as follows:
S2-1: A chiral iodized salt (R-α-MBA)I was prepared: A round-bottomed flask of 25 mL was ultrasonically cleaned with acetone, is opropanol, ethanol, and deionized water in sequence, dried by nitrogen, dried at 80° C. for 1 hour, and then cooled for later use. A quantity of R-type chiral amine (R-MBA) (5.3 mL) and a quantity of methanol (20 mL) from a fume food were put into the round-bottomed flask, then First stirring was performed to dissolve fully, and the mixture solution was transferred to an ice bath environment at 0° C. A quantity of hydriodic acid (5 mL) was added dropwisely in 15 minutes to obtain a mixture, and the mixture was stirred for 2 hours. The ice bath was removed, and a solvent was evaporated under the condition of an oil bath at 80° C. to obtain (R-α-MBA)I white powder. The powder was collected and washed third with ether, and then dried in a vacuum overnight.
S2-2: A chiral perovskite (R-α-MBA)PbI₃ was prepared: A glass bottle of 2 mL was ultrasonically cleaned with acetone, isopropanol, ethanol and deionized water in sequence, dried by nitrogen, dried at 80° C. for 1 hour and then cooled for later use. 460 mg of PbI₂, 248 mg of (R-α-MBA)I and 1 mL of DMF from a glove box were mixed in the glass bottle of 2 mL to obtain a mixture, and the mixture was completely dissolved by stirring the mixture at 60° C. for 2 hours to obtain an (R-α-MBA)PbI₃ solution (1 mol/L). The (R-α-MBA)PbI₃ solution (1 mol/L) of 300 μL and the DMF of 700 μL were mixed to obtain an (R-α-MBA)PbI₃ solution (0.3 mol/L) for later use. The X-ray diffraction (XRD) spectrum, ultraviolet-visible (UV-visible) absorption spectrum and circular dichroism (CD) absorption spectrum of (R-α-MBA)PbI₃ are shown in FIG. 9, FIG. 10 and FIG. 11 respectively.
S2-3:A SWNTs was prepared: A glass bottle of 50 mL was ultrasonically cleaned with acetone, isopropanol, ethanol and deionized water in sequence, dried by nitrogen, dried at 80° C. for 1 hour and then cooled for later use. 5 mg of poly [9-(1-octylnonyl)-9H-carbazole](PCz), 5 mg of carbon-nanotube powder first and 20 mL of toluene second were mixture into the glass bottle, and an ultrasonic treatment was performed for 1 hour to obtain a carbon-nanotube precursor solution of. The precursor solution was centrifuged at a parameter of 15000 g for 1 hour to remove insoluble substances, and a supernatant of the precursor solution was taken out and diluted with chloroform of the same volume to obtain the SWNT. The Raman spectrum of the SWNT is shown in FIG. 7, and the corresponding Raman shift (1600) peak proves that high-quality SWNT with semiconductor properties was obtained.
S2-4:A 1D-R based UV PAS device was prepared: The SiO₂ substrate with a thickness of 300 nm was ultrasonically cleaned with acetone, isopropanol, ethanol and deionized water in sequence, and then immersed in a dispersion solution of the SWNT for 24 hours, and then the SiO₂ substrate was taken out and baked at 120° C. for 15 minutes to deposit a SWNT layer. Au/Ti electrodes is prepared by photoetching and electron beam evaporation. The thickness of Au and Ti were 45 nm and 5 nm, respectively, and the width of a channel of the electrode was 10 microns. The SiO₂ substrate with the SWNT and the electrodes was was processed by ultraviolet ozone, and then an R-type chiral perovskite solution (50 μL, 0.3 mol/L) was spin-coated in nitrogen atmosphere at a speed of 4000 rpm for 30 seconds by a spin coater SWNT to obtain a chiral perovskite layer. The thickness of the chiral perovskite layer was about 70 nm, and then the chiral perovskite layer was placed on a hot plate and annealed at 95° C. for 15 minutes. Finally, the 1D-R based UV PAS device was obtained.
S2-5: Bionic function test of the 1D-R based UV PAS device was performed. Monochromatic light source, linear polarizer, quarter-wave plate, probe station and semiconductor analyzer were used for synaptic biomimetic test of polarization regulation. The monochromatic light was generated by the LED purchased from Thorlabs, the frequency of the polarized light signal was controlled by a signal generator, and the 1D-R based UV PAS device was connected to the Keithley 4200 through two Au probes of the probe station. The response of the 1D-R based UV PAS device excited by consecutive UV LCP/RCP light spikes (395 nm, 10 uWcm⁻²) is shown in FIG. 12.

### Embodiment 3

The preparation method of the CPL-resolved PAS device in the example 3 of the present disclosure was as follows:
S3-1: A chiral iodized salt (S-α-MBA)I was prepared: Around-bottomed flask of 25 mL was ultrasonically cleaned with acetone, isopropanol, ethanol and deionized water in sequence, dried by nitrogen, dried at 80° C. for 1 hour and then cooled for later use. A quantity of S-type chiral amine (S-MBA) (5.3 mL) and a quantity of methanol (20 mL) from a fume hood were put into the round-bottomed flask, then stirred for dissolving fully, and then transferred to an ice bath environment in at 0° C. A quantity of hydriodic acid (5 mL) was added dropwisely in 15 minutes to obtain a mixture, and the mixture was stirred for 2 hours. The ice bath was removed, and a solvent was evaporated under the condition of oil bath at 80° C. to obtain (S-α-MBA)I white powder. The powder was collected and then washed twice with ether, and then dried in a vacuum overnight.
S3-2: A chiral perovskite (S-α-MBA)PbI₃ was prepared: A glass bottle of 2 mL was ultrasonically cleaned with acetone, isopropanol, ethanol and deionized water in sequence, dried by nitrogen, dried at 80° C. for 1 hour and then cooled for later use. 460 mg of PbI₂, 248 mg of (S-α-MBA)I and 1 mL of DMF from a glove box were mixed in the glass bottle of 2 mL to obtain a mixture, and the mixture was completely dissolved by stirring the mixture at 60° C. for 2 hours to obtain an (S-α-MBA)PbI₃ solution (1 mol/L). The (S-α-MBA)PbI₃ solution (1 mol/L) of 300 μL and the DMF of 700 μL were mixed to obtain an (S-α-MBA)PbI₃ solution (0.3 mol/L) for later use. The X-ray diffraction (XRD) spectrum, ultraviolet-visible (UV-visible) absorption spectrum and circular dichroism (CD) absorption spectrum of (S-α-MBA)PbI₃ are shown in FIG. 4, FIG. 5 and FIG. 6 respectively.
S3-3: A SWNT was prepared: A glass bottle of 50 mL was ultrasonically cleaned with acetone, isopropanol, ethanol and deionized water in sequence, dried by nitrogen, dried at 80° C. for 1 hour and then cooled for later use. 5 mg of poly [9-(1-octylnonyl)-9H-carbazole](PCz), 5 mg of carbon-nanotube powder first and 20 mL of toluene second were mixed in the glass bottle, and an ultrasonic treatment was performed for 1 hour to obtain a carbon-nanotube precursor solution. The precursor solution was centrifuged at a parameter of 15000 g for 1 hour to remove insoluble substances, and a supernatant of the precursor solution was taken out and diluted with chloroform of the same volume to obtain the SWNT. The Raman spectrum of the SWNT is shown in FIG. 7, and the corresponding Raman shift (1600) peak proves that high-quality SWNT with semiconductor properties was obtained.
S3-4: A 1D-S based UV PAS device was prepared: A SiO₂ substrate with a thickness of 300 nm was ultrasonically cleaned with acetone, isopropanol, ethanol and deionized water in sequence, and then was immersed in a dispersion solution of the SWNT solution for 24 hours, and then the SiO₂ substrate was took out and then baked at 120° C. for 15 minutes to deposit an SWNT layer. Au/Ti electrodes is prepared by photoetching and electron beam evaporation. The thickness of Au and Ti were 45 nm and 5 nm, respectively, and the width of a channel of the electrodes was 10 microns. The SiO₂ substrate with the SWNT and the electrodes is processed by ultraviolet ozone, and then an S-type chiral perovskite solution (50 μL, 0.3 mol/L) was spin-coated in nitrogen atmosphere at a speed of 4000 rpm for 30 seconds by a spin coater to obtain a chiral perovskite layer. The thickness of the chiral perovskite layer was about 70 nm, and then the chiral perovskite layer was placed on a hot plate and annealed at 95° C. for 15 minutes. Finally, the 1D-S based UV PAS device was obtained.
S3-5: Bionic function test of the 1D-S based UV PAS device was performed. Monochromatic light source, linear polariscope, quarter-wave plate, probe station, and semiconductor analyzer were used for synaptic biomimetic test of polarization regulation. The monochromatic light was generated by the LED purchased from Thorlabs, the frequency of the polarized light signal was controlled by a signal generator, and the 1D-S based UV PAS device was connected to the Keithley 4200 through two Au probes of the probe station. The response of the 1D-S based UV PAS device excited by consecutive UV LCP light spikes (395 nm) at different intensities is shown in FIG. 13.

In summary, the present disclosure provides a circular polarization-resolved ultraviolet photonic artificial synapse (CPL-resolved UV PAS) device based on H-PVK/SWNT heterostructure. Using the chiroptic response characteristics of the H-PVK materials and the carrier conduction characteristics of the SWNT, the H-PVK/SWNT heterostructure is able to achieve nano-ampere-level distinguishable photocurrent response for circular-polarization UV light with different chirality. In addition, the CPL-resolved PAS device obtained by the present disclosure has good stability and can be prepared at a large scale.

It should be understood that the application of the present disclosure is not limited to the above embodiments. For those ordinary skilled in the art, improvements or transformations can be made according to the above embodiments, and all these improvements and transformations should fall within the protection scope of the claims attached to the present disclosure.

What is claimed is:

1. A heterostructure based on a helical chiral perovskite (H-PVK) and a single-wall carbon nanotube (SWNT), wherein the heterostructure comprises a H-PVK layer and a SWNT layer, and the H-PVK layer and the SWNT layer contact and overlap, and a heterojunction is formed between the H-PVK layer and the SWNT layer.

2. The heterostructure based on the H-PVK and the SWNT of claim 1, wherein the H-PVK comprises one or more of (S-α-MBA)PbI₃, (R-α-MBA)PbI₃, (S-NEA)PbI₃, (R-NEA)PbI₃, (S-MPA)PbI₃, (R-MPA)PbI₃, (S-α-MBA)PbBr₃, and (R-α-MBA)PbBr₃.

3. The heterostructure based on the H-PVK and the SWNT of claim 1, wherein a thickness of the H-PVK layer is 40-90 nm, and a thickness of the SWNT layer is 2-10 nm.

4. A method for preparing the heterostructure based on the H-PVK and the SWNT of claim 1, comprising the following steps:
providing a substrate;
depositing a SWNT layer on the substrate; and
depositing a H-PVK layer on the SWNT layer.

5. The method of claim 4, wherein the step of depositing the SWNT layer on the substrate is by a solution method.

6. The method of claim 4, wherein the step of depositing the H-PVK layer on the SWNT layer is by solution method.

7. A photonic artificial synapse (PAS) device, comprising: a heterostructure based on a helical chiral perovskite (H-PVK) and a single-wall carbon nanotube (SWNT); the heterostructure comprises a H-PVK layer and a SWNT layer, and the H-PVK layer and the SWNT layer contact and overlap; and a heterojunction is formed between the H-PVK layer and the SWNT layer.

8. The PAS device of claim 7, further comprising: a substrate, the SWNT layer arranged on the substrate, electrodes arranged on two ends of the SWNT layer, the H-PVK layer arranged on an area uncovered by the electrode of the SWNT layer; and the heterojunction is formed between the H-PVK layer and the SWNT layer.

9. The PAS device of claim 8, wherein the substrate is a silicon wafer, a sapphire, or a quartz, with a SiO₂ layer on a surface of the substrate; and the SiO₂ layer is attached to the SWNT layer;
the electrodes arranged on the two ends includes a first electrode and a second electrode;
a material of the first electrode includes one of Au, Pt, Ag, ITO, Al, and Ni; and
a material of the second electrode includes one of Cr, Ti, Ag, ITO, Al, and Ni.

10. The PAS device of claim 8, wherein the H-PVK comprises one or more of (S-α-MBA)PbI₃, (R-α-MBA)PbI₃, (S-NEA)PbI₃, (R-NEA)PbI₃, (S-MPA)PbI₃, (R-MPA)PbI₃, (S-α-MBA)PbBr₃, and (R-α-MBA)PbBr₃.

11. The PAS device of claim 8, wherein a thickness of the H-PVK layer is 40-90 nm, and a thickness of the SWNT layer is 2-10 nm.

12. A method for preparing a photonic artificial synapse (PAS) device, comprising the following steps:
providing a substrate;
depositing a SWNT layer on the substrate;
depositing electrodes on two ends of the SWNT layer;
depositing a H-PVK layer on an area uncovered by the electrodes of the SWNT layer.

13. The method of claim 12, wherein the step of depositing the SWNT layer on the substrate is by a solution method.

14. The method of claim 13, wherein the step of depositing the SWNT layer on the substrate is by the solution method comprises:
providing a SWNT disperser; and
immersing the substrate in the SWNT disperser for 12-48 hours, and then taking the immersed substrate out, and heating the immersed substrate at 90-150° C. for 15-180 minutes, and depositing the heated substrate to obtain the SWNT layer on the substrate.

15. The method of claim 12, wherein the step of depositing the H-PVK layer on the area uncovered by the electrodes of the SWNT layer is by a solution method.

16. The method of claim 15, wherein the step of depositing the H-PVK layer on the area uncovered by the electrodes of the SWNT layer by the solution method comprises:
providing a H-PVK solution; and
spin-coating the H-PVK solution on the area uncovered by the electrodes of the SWNT layer at a spin speed of 3500-5000 rpm for 30-50 seconds in an inert atmosphere, then annealing the spin-coated H-PVK at 80-100° C. for 10-60 minutes, and depositing the annealed H-PVK on the area uncovered by the electrodes of the SWNT layer to obtain the H-PVK layer.

17. The method of claim 12, wherein the step of depositing the electrodes on the two ends of the SWNT layer is by a photo etching and an electron-beam evaporation.
